(19) United States
(12) Patent Application Publication
(10) Pub. No.: US 2024/0053402 A1
(43) Pub. Date: Feb. 15, 2024

(54) METHOD FOR ANALYZING BATTERY LIFE DEGRADATION, STORAGE MEDIUM, AND ELECTRONIC DEVICE

(71) Applicant: Shanghai Makesens Energy Storage Technology Co., Ltd., Shanghai (CN)

(72) Inventors: Guopeng ZHOU, Shanghai (CN); Haowen REN, Shanghai (CN); Peng DING, Shanghai (CN); Xiaohua CHEN, Shanghai (CN); Enhai ZHAO, Shanghai (CN); Xiao YAN, Shanghai (CN)

(73) Assignee: Shanghai Makesens Energy Storage Technology Co., Ltd., Shanghai (CN)

(21) Appl. No.: 18/229,685

(22) Filed: Aug. 3, 2023

(30) Foreign Application Priority Data
Aug. 10, 2022 (CN) 2022109571031

(51) Int. Cl. G01R 31/367; G01R 31/392

(52) U.S. Cl. CPC G01R 31/367; G01R 31/392

(57) ABSTRACT

A method for analyzing battery life degradation, a storage medium, and an electronic device are provided. The method includes: obtaining battery data of a device, where the battery data includes a voltage and a current of a battery of the device; estimating an open circuit voltage of the battery based on the battery data; establishing a function curve between a state of charge and the open circuit voltage of the battery; extracting a life degradation curve based on the function curve; and performing life degradation analysis on the battery based on the life degradation curve. In the present disclosure, a dQ/dV curve of the battery can be accurately extracted under complex working conditions, thereby ensuring accuracy of the battery life degradation analysis, and achieving desirable practical applicability under complex working conditions.

### CROSS REFERENCE TO RELATED APPLICATION

The present application claims the benefit of priority to Chinese Patent Application No. CN 2022109571031, entitled “METHOD FOR ANALYZING BATTERY LIFE DEGRADATION, STORAGE MEDIUM, AND ELECTRONIC DEVICE”, filed with CNIPA on Aug. 10, 2022, the disclosure of which is incorporated herein by reference in its entirety for all purposes.

### FIELD OF TECHNOLOGY

The present disclosure relates to lithium battery analysis, in particular, to a method for analyzing battery life degradation, a storage medium, and an electronic device.

### BACKGROUND

In recent years, with increasingly more attention paid to the field of new energy, lithium batteries have gradually become the preferred energy source for new-energy vehicles and charging stations due to characteristics such as high energy density and long cycle life. However, in recent years, cases of lithium battery fires have made people realize that there are still some problems with lithium battery technology, such as capacity degradation and internal short circuits. Therefore, it is necessary to study the failure and degradation mechanisms of lithium batteries. Further research on the degradation mechanism of batteries can also clarify the reaction mechanism of anodes, which is of great significance for understanding the failure mechanism of lithium batteries.

At present, the existing method for analyzing the failure and degradation mechanism needs to smooth a curve after the curve is extracted. Moreover, its requirements for data are very high, and it is difficult to extract curves accurately under complex conditions.

Therefore, how to extract curves accurately under complex conditions to realize accurate analysis of lithium battery life degradation has become an urgent technical problem to be solved by those skilled in the art.

### SUMMARY

An aspect of the present disclosure provides a method for analyzing battery life degradation. The method for analyzing battery life degradation comprises: obtaining battery data of a device, wherein the battery data comprises a voltage and a current of a battery of the device; estimating an open circuit voltage of the battery based on the battery data; establishing a function curve between a state of charge and the open circuit voltage of the battery; extracting a life degradation curve based on the function curve; and performing life degradation analysis on the battery based on the life degradation curve.

In an embodiment of the present disclosure, the step of establishing the function curve between the state of charge and the open circuit voltage of the battery comprises: establishing an adaptive iterative calculation model, and estimating the open circuit voltage of the battery by using the adaptive iterative calculation model; and obtaining the function curve between the state of charge and the open circuit voltage of the battery by polynomial fitting.

In an embodiment of the present disclosure, the step of establishing the adaptive iterative calculation model, and estimating the open circuit voltage of the battery by using the adaptive iterative calculation model comprises: establishing the adaptive iterative calculation model based on a first-order RC equivalent circuit; performing bilinear transformation on the adaptive iterative calculation model; determining a to-be-estimated-parameter matrix and an input variable matrix; and determining the open circuit voltage of the battery based on the to-be-estimated-parameter matrix and the input variable matrix.

In an embodiment of the present disclosure, the step of obtaining the function curve between the state of charge and the open circuit voltage of the battery by polynomial fitting comprises: setting a forgetting factor, and setting an initial value of the forgetting factor, wherein the forgetting factor represents a degree to which an estimation result at a previous moment is forgotten; adaptively adjusting the forgetting factor based on a preset condition during each iteration of the adaptive iterative calculation model; inputting the voltage and the current of the battery and the state of charge of the battery into the adaptive iterative calculation model to obtain the open circuit voltage; and obtaining the function curve between the state of charge and the open circuit voltage of the battery by polynomial fitting.

In an embodiment of the present disclosure, the step of extracting the life degradation curve based on the function curve comprises: calculating capacity differentials based on the function curve, which is performed every time the state of charge changes during a complete charging and discharging process; and obtaining the life degradation curve based on the capacity differentials.

In an embodiment of the present disclosure, the step of obtaining the battery data of the device comprises: continuously obtaining the battery data of the device at a preset data sampling interval.

In an embodiment of the present disclosure, before the step of obtaining the battery data of the device, the method for analyzing battery life degradation further comprises: obtaining a piece of battery data in advance, and analyzing an actual working condition of a power station based on the piece of battery data obtained in advance.

In an embodiment of the present disclosure, the step of performing life degradation analysis on the battery based on the life degradation curve comprises: analyzing a life degradation mechanism of the battery based on variations of different peaks, position shifts of the peaks, and sharpness variations of the peaks of the life degradation curve, wherein analyzing the life degradation mechanism of the battery further comprises: analyzing a loss of circulating lithium and a loss of a negative active material through the variations of the peaks of the life degradation curve.

Another aspect of the present disclosure provides a non-transitory computer-readable storage medium, storing a computer program. When the computer program is executed by a processor, the method for analyzing battery life degradation is implemented.

A further aspect of the present disclosure provides an electronic device, comprising: a processor and a memory, wherein the memory is configured to store a computer program, and the processor is configured to execute the computer program stored in the memory, so that the electronic device performs the method for analyzing battery life degradation.

As described above, the method for analyzing battery life degradation, the storage medium, and the electronic device of the present disclosure have the following beneficial effects.
(1) The present disclosure provides a method for extracting a life degradation curve (that is, a dQ/dV curve of a lithium battery) under complex working conditions. The extraction method is simple and only requires obtaining a state of charge (SOC)-open circuit voltage (OCV) curve, thereby solving the problem in the prior that that it is difficult to accurately extract the dQ/dV curve of the battery under complex working conditions, and achieving desirable practical applicability under complex working conditions.
(2) The implementation of the method is efficient, as it occupies minimal memory space and does not interfere with other functions. Additionally, the speed of operation is impressive. For instance, when analyzing the life degradation of a certain battery or battery module using this method to extract the dQ/dV curve, it only takes about 1 second to process a whole day's worth of data.

### BRIEF DESCRIPTION OF THE DRAWINGS

FIG. 1 is a schematic flowchart of a method for analyzing battery life degradation according to an embodiment of the present disclosure.

FIG. 2 is a first-order RC equivalent circuit diagram of a method for analyzing battery life degradation according to an embodiment of the present disclosure.

FIG. 3 is a current variation diagram of a method for analyzing battery life degradation according to an embodiment of the present disclosure.

FIG. 4 is an error diagram of terminal voltage curve estimation of a method for analyzing battery life degradation according to an embodiment of the present disclosure.

FIG. 5 is an SOC-OCV curve of a method for analyzing battery life degradation according to an embodiment of the present disclosure.

FIG. 6 is an SOC-dQ/dV curve of a method for analyzing battery life degradation according to an embodiment of the present disclosure.

FIG. 7 is a comparison diagram of small battery aging test curves of a method for analyzing battery life degradation according to an embodiment of the present disclosure.

FIG. 8 is a block diagram of an electronic device according to an embodiment of the present disclosure.

### REFERENCE NUMERALS

8 Electronic device
81 Processor
82 Memory
S11-S15 Steps

### DETAILED DESCRIPTION

Implementations of the present disclosure are described below through specific examples, and a person skilled in the art can easily understand other advantages and effects of the present disclosure from the contents disclosed in this specification. The present disclosure may further be implemented or applied through other different specific implementations, and various details in this specification may also be modified or changed based on different viewpoints and applications without departing from the spirit of the present disclosure. It should be noted that the following embodiments and features in the embodiments may be combined with each other in case of no conflicts.

It should be noted that, the drawings accompanying the following embodiments show the basic idea of the present disclosure in a schematic manner, and only components closely related to the present disclosure are shown in the drawings. The drawings are not necessarily drawn according to the number, shape and size of the components in actual implementation; during the actual implementation, the type, quantity and proportion of each component can be changed as needed, and the layout of the components can also be more complicated.

Through the method for analyzing battery life degradation, the storage medium, and the electronic device consistent with the present disclosure, a dQ/dV curve of the battery can be accurately extracted under complex working conditions, thereby ensuring accuracy of the battery life degradation analysis, and achieving desirable practical applicability under complex working conditions. Compared with existing heuristic algorithms, and the like for extracting dQ/dV curves. This method is simple and highly applicable, and the extracted curve does not require smoothing. It also has good practical applicability for complex working conditions such as frequency regulation of power stations or variable motions of electric vehicles.

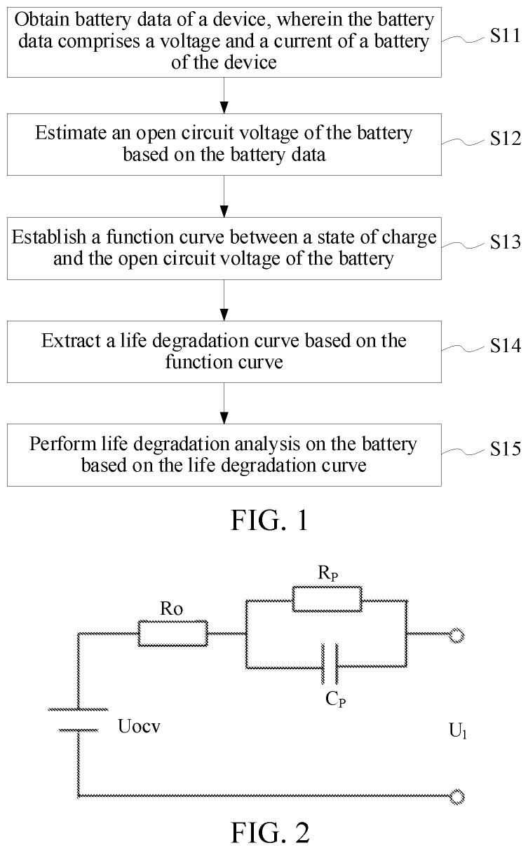

The principle and implementation of the method for analyzing battery life degradation, the storage medium, and the electronic device of the present disclosure are to be described in detail with reference to FIG. 1 to FIG. 8, so that a person skilled in the art can understand the method for analyzing battery life degradation, the storage medium, and the electronic device without creative efforts.

Refer to FIG. 1, which is a schematic flowchart of a method for analyzing battery life degradation according to an embodiment of the present disclosure. As shown in FIG. 1, the method for analyzing battery life degradation comprises steps S11 to S15.

S11: Obtaining battery data of a device, wherein the battery data comprises a voltage and a current of a battery of the device.

In an embodiment, the battery data of the device is continuously obtained at a preset data sampling interval.

Specifically, battery data of a power station or an electric vehicle is collected at regular intervals, and the collected data mainly comprises a working time, current, voltage, temperature, State of charge (SoC) of a battery of the power station or the electric vehicle, and the like.

In practical applications, a built-in chip of a battery management system (BMS) collects the working time, current, voltage, temperature, state of charge of the battery. An electronic device performing the method for analyzing battery life degradation is provided with a module communicating with the BMS, thereby obtaining the battery data such as the working time, current, voltage, temperature, state of charge of the battery.
S12: Estimating an open circuit voltage of the battery based on the battery data.
S13: Establishing a function curve between the state of charge of the battery and the open circuit voltage (OCV) of the battery.

Refer to FIG. 2, which is a first-order RC equivalent circuit diagram of a method for analyzing battery life degradation according to an embodiment of the present disclosure. The present disclosure estimates the open circuit voltage of the battery based on the first-order RC equivalent circuit and by an adaptive forgetting-factor-recursive-least-squares (FFRLS) method, and obtains an SOC-OCV curve by polynomial fitting. S13 specifically comprises the following steps.
(1) Establishing an adaptive iterative calculation model, and estimating the open circuit voltage of the battery by using the adaptive iterative calculation model.

In an embodiment, step (1) of S13 further comprises the following steps:
(1.1) Establishing the adaptive iterative calculation model based on the first-order RC equivalent circuit.

Specifically, still referring to FIG. 2, the first-order RC equivalent circuit is adopted, and the corresponding formulas are as follows:

$$\dot{{U}_{p}} = \frac{{U}_{p}}{{R}_{p} {C}_{p}} + \frac{{i}_{l}}{{C}_{p}} \\ {U}_{l} = {U}_{ocv} - {U}_{p} - {i}_{l} {R}_{o}$$

Uₗ represents a battery terminal voltage, U_{ocv} represents an open circuit voltage, Uₚ represents a polarization voltage, and ii represents a current. A transfer function based on the above formulas is given by:

$$G ( s ) = \frac{{U}_{l} ( s ) - {U}_{ocv} ( s )}{{i}_{l} ( s )} = - ( {R}_{o} + \frac{{R}_{p}}{1 + {R}_{p} {C}_{p} s} )$$

The transfer function is equivalent to:

$${U}_{l} ( s ) - {U}_{ocv} ( s ) = - {i}_{l} ( s ) ( {R}_{o} + \frac{{R}_{p}}{1 + {R}_{p} {C}_{p} s} )$$

(1.2) Performing bilinear transformation on the adaptive iterative calculation model.

Specifically, by bilinear transformation, the above equivalent transfer function is transformed into:

δU_{l,k}=α₁×δU_{l,k-1}+α₂×i_{l,k}+α₃λi_{l,k-1}

a₁, a₂, and a₃ are coefficients related to model parameters, which vary in the process of parameter estimation. δU_{l,k}=U_{l,k}−U_{ocv,k} represents a difference between a terminal voltage and the open circuit voltage during the k^{th} sampling. The open circuit voltage U_{ocv} is associated with the state of charge and the temperature of the battery. Since the sampling interval is very short, for example, 15 s, changes of the state of charge and temperature between adjacent sampling intervals are neglectable, and therefore it is assumed that U_{ocv,k}=U_{ocv,k-1}, and therefore the above formula is then transformed into:

U_{l,k}=(1−α₁)×U_{ocv,k}+α₁×U_{l,k-1}+α₂×i_{l,k}+α₃×i_{l,k-1}
(1.3) Determining a to-be-estimated-parameter matrix and an input variable matrix. Here, determining the matrices refers to determining their expressions based on related parameters. The same may also apply to other instances of “determining” throughout this specification.

The to-be-estimated-parameter matrix xₖ and the input variable matrix Aₖ are determined to be given by:

xₖ=[(1−α₁)U_{ocv,k}α₁α₂α₃]^{T}

Aₖ=[1U_{l,k-1}i_{l,k}i_{l,k-1}]^{T}

U_{l,k-1} represents a terminal voltage at a moment k−1, i_{l,k} represents a current at a moment k, and i_{l,k-1} represents a current at a moment k−1. All the above input variables are sampled and obtained when S11 is performed. The moment k represents a present moment of sampling, and k−1 represents a previous moment of the sampling. xₖ[0] represents the first parameter of the matrix xₖ.
(1.4) Determining the open circuit voltage of the battery based on the to-be-estimated-parameter matrix and the input variable matrix.

The terminal voltage, that is, the open circuit voltage U_{ocv}, may be given by the to-be-estimated-parameter matrix and the input variable matrix.

$${U}_{ocv , k} = \frac{{x}_{k} [ 0 ]}{1 - {a}_{1}}$$

(2) Obtaining the function curve between the state of charge and the open circuit voltage of the battery by polynomial fitting.

In an embodiment, step (2) of S13 specifically comprises the following steps.
(2.1) Setting a forgetting factor, and setting an initial value of the forgetting factor, wherein the forgetting factor represents a degree to which an estimation result at a previous moment is forgotten.
(2.2) Adaptively adjusting the forgetting factor based on a preset condition during each iteration of the adaptive iterative calculation model.

Specifically, when the open circuit voltage of the battery is estimated by the FFRLS method, the forgetting factor A represents a degree to which a result of a previous iteration is forgotten. When the forgetting factor is 1, it indicates that the result of the previous iteration is completely preserved. When the forgetting factor is 0.9, it indicates that only 90% of the result of the previous iteration is remembered. It is recommended that the forgetting factor should be in a range of 0.9 to 1.

In practical applications, the parameter matrix xₖ is based on an adaptive FFRLS iterative calculation model. In order to ensure the stability of the results, the forgetting factor λ is introduced. After the initial value of λ is set, λ is adjusted adaptively during each iteration based on set conditions, and the value of λ is always between 0.9 and 1 in the adaptive process. The process of iterative calculation is similar to a process of Kalman filtering to calculate the parameter matrix xₖ at different moments. The specific iterative calculation process is given as follows:

$${K}_{k} = {P}_{k - 1} {{A}_{k}^{T} [ {A}_{k} {P}_{k - 1} {A}_{k}^{T} + λ ]}^{- 1} \\ {\hat{x}}_{k} = {\hat{x}}_{k - 1} + {K}_{k} [ {U}_{l , k} - {A}_{k} {\hat{x}}_{k - 1} ] \\ {P}_{k} = \frac{1}{λ} [ I - {K}_{k} {A}_{k} ] {P}_{k - 1}$$

Pₖ is a covariance matrix of state estimation errors, Kₖ is the gain of each iteration, and I is an identity matrix.
(2.3) Inputting the voltage and the current of the battery and the state of charge of the battery into the adaptive iterative calculation model to obtain the open circuit voltage of the battery.

Specifically, the current, the voltage, and the state of charge of each sampling are inputted into the model to realize online estimation and obtain the terminal voltage U_{ocv}. Here, “online estimation” refers to continuous estimation of voltage in real-time.

In practical applications, according to the step (1.3) of S13, expressions of the to-be-estimated-parameter matrix xₖ and the input variable matrix Aₖ are determined, and the current and the voltage are inputted into the input variable matrix Aₖ. The temperature is not reflected in the expressions, because the temperature change is within 1° C., whose influence on the state of charge can be ignored. After the U_{ocv} is obtained, an SOC-OCV relation curve is established according to the formula (2.4) in step (2) of S13.

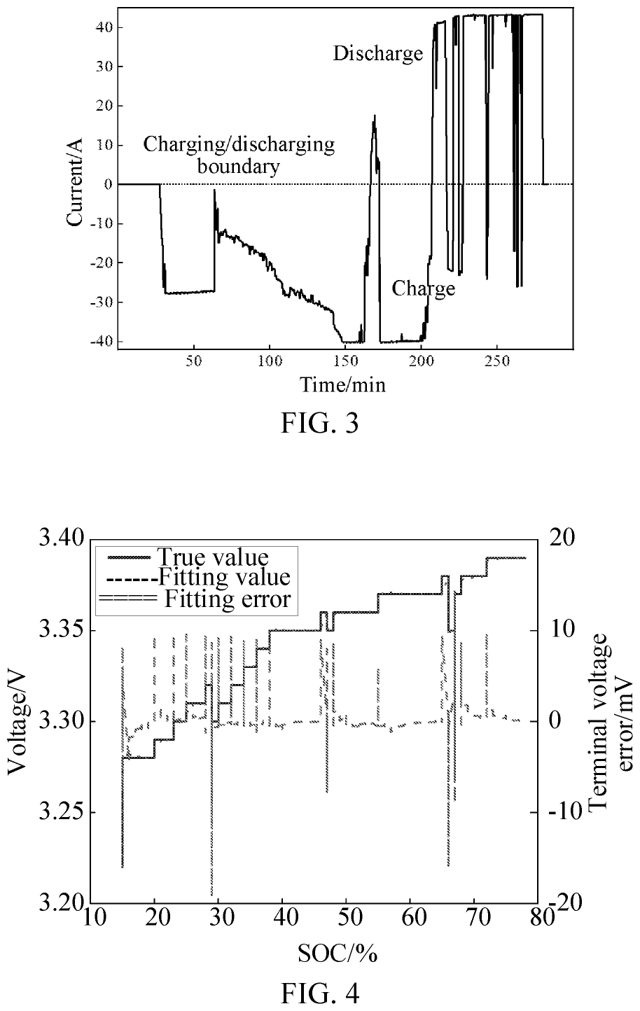

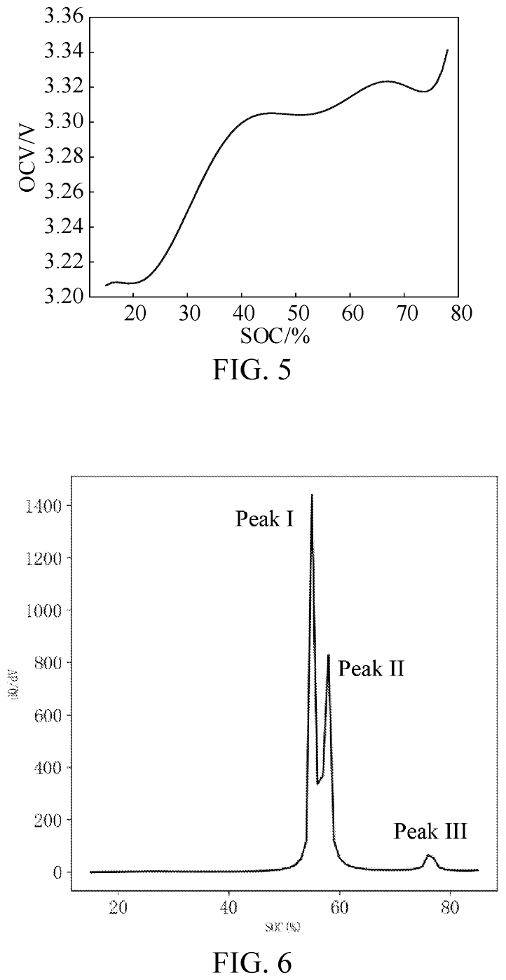

Referring to FIG. 4, comparison between the estimated terminal voltage and the sampled voltage and an error therebetween are presented. It can be seen that the estimated terminal voltage is very close to the sampled battery voltage, and the two curves almost coincide. It can be seen from FIG. 4 that the maximum error is within 20 mV, which indicates that the present estimation method is reliable. FIG. 5 shows an estimated OCV curve. The estimated OCV curve shows the open circuit voltage of the battery varying with the state of charge of the battery. It should be noted that when the state of charge is around 70, the OCV curve decreases slightly. This is because the power station changes from a previous working condition of charging to a current working condition of discharging in this period of time, and after the working condition changes, no change in the state of charge is detected from the uploaded data. The change in working conditions corresponds to the operation of the power station near 170 minutes in FIG. 3, where the power station changes from charging to discharging instantaneously.
(2.4) Obtaining the function curve between the state of charge and the open circuit voltage of the battery by polynomial fitting.

Specifically, the terminal voltage U_{ocv} is estimated, and the OCV curve is approximated using the following polynomial equation.

$${U}_{ocv} ( SOC ) = {\sum }_{n = 0}^{7} {b}_{n} \times {SOC}^{n}$$

n is the degree of a polynomial term, bₙ is a coefficient of an n^{th} degree term of the polynomial, and bₙ is to be solved.

S14: Extracting a life degradation curve based on the function curve.

In an embodiment, S14 specifically comprises the following steps.
(1) Calculating capacity differentials based on the function curve.

Specifically, after the SOC-OCV curve is obtained, a dQ/dV value is calculated based on:

$$\frac{dQ}{{dV}_{( k )}} = \frac{{SOC}_{k} - {SOC}_{k - 1}}{{OCV}_{k} - {OCV}_{k - 1}}$$

K represents a moment when the state of charge changes for the k^{th} time, and k−1 represents a moment when the state of charge changes for the (k−1)^{th} time.
(2) Calculating the capacity differentials every time the state of charge changes during a complete charging and discharging process.

Specifically, the capacity differentials are calculated every time the state of charge changes during the complete charging and discharging process, that is, dQ/dV.
(3) Obtain the life degradation curve based on the capacity differentials.

As a result, the changing state of charge corresponds to a plurality of values of dQ/dV, thereby obtaining a life degradation curve, that is, an SOC-dQ/dV curve (dQ/dV curve for short).

The SOC-dQ/dV curve is specifically obtained by: selecting points where the state of charge changes, calculating the quotients of the SOC changes and the corresponding voltage changes at these points (i.e., dQ/dV), using values of dQ/dV as the vertical axis, and using values of the state of charge as the horizontal axis. Since the SOC-dQ/dV curve of a lithium-ion battery is an effective tool for analyzing whether the battery is degradation, it is possible to analyze the degradation mechanism of the battery without disassembling the battery by using the SOC-dQ/dV curve.

Refer to FIG. 6, which is an SOC-dQ/dV curve graph of a method for analyzing battery life degradation according to an embodiment of the present disclosure. FIG. 6 correspondingly shows an actual working condition of a battery type. A one-to-one correspondence between the SOC and the OCV is obtained through the SOC-OCV curve obtained by polynomial fitting. According to the present disclosure, then dQ/dV is calculated, and the SOC-dQ/dV curve is drawn.

S15: Performing life degradation analysis on the battery based on the life degradation curve.

In an embodiment, S15 specifically comprises the following step:
analyzing a life degradation mechanism of the battery based on variations of different peaks, position shifts of the peaks, and sharpness variations of the peaks of the life degradation curve, wherein analyzing the life degradation mechanism of the battery further comprises: analyzing a loss of circulating lithium and a loss of a negative active material through the variations of the peaks of the life degradation curve.

The SOC-dQ/dV curve is of great significance to the degradation mechanism and fault analysis of the lithium battery. With the use of the lithium battery, the SOC-dQ/dV curve of the lithium battery after different cycles may be drawn, and the life degradation mechanism of the lithium-ion battery is analyzed by observing attenuation variations and sharpness degrees of peaks of the SOC-dQ/dV curve. It can be seen from FIG. 6 that the curve has three obvious peaks in total, each representing an electrochemical reaction. A loss of circulating lithium and a loss of a negative active material are analyzed through the variations of the peaks. For the life degradation analysis of the battery in FIG. 6, refer to the curve analysis table below, i.e., Table 1 for details.

TABLE 1
Curve analysis table

| Phenomenon | Peak I | Peak II | Another peaks |
|---|---|---|---|
| Loss of circulating lithium | Constant at an | Decline | Constant |
| | initial stage and | | |
| | decline at a later | | |
| | stage | | |
| Loss of negative lithiated | Decline | Decline | Decline |
| active material | | | |
| Loss of negative delithiated | Decline | Rise | Decline |
| active material | | | |

| | |
|---|---|
| The internal resistance | Translation |
| increases | |

In an embodiment, before step S11, the method for analyzing battery life degradation further comprises: obtaining a piece of battery data in advance, and analyzing an actual working condition of a power station based on the piece of battery data obtained in advance.

Specifically, referring to FIG. 3, a current variation of a cluster of the power station in a period of time is presented, wherein the current sampling interval is 15 s. Structurally, the power station is arranged according to a cluster-box-cell structure, which is connected in series as a whole, and a current of a cluster is a current of a cell. It may be seen from FIG. 3 that the working condition of the power station is complex, the current is changing irregularly, and the current has a great instantaneous change at some moments, which is very different from simple working conditions such as a constant current. Moreover, near 170 min of operation of the power station, the working condition changes from discharging to charging almost instantaneously, and after 210 min of operation, the working condition repeatedly switches between charging and discharging quickly, which is much more complex than the simple working conditions in experiments.

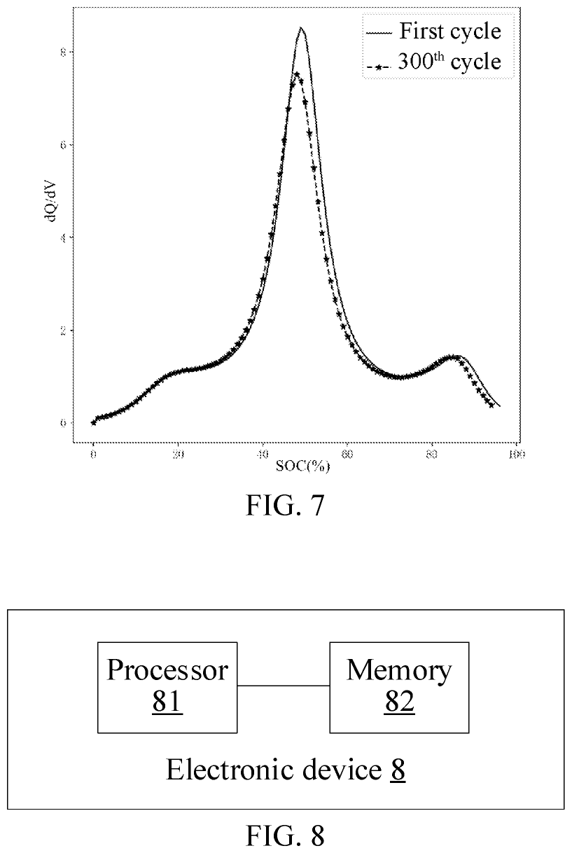

Refer to FIG. 7, which is a comparison diagram of battery high-temperature aging test curves of a method for analyzing battery life degradation according to an embodiment of the present disclosure. FIG. 7 shows a working condition of an aging test of a battery of a type different from that of FIG. 6 in a 40° C. incubator, showing an application case of the present disclosure on another type of lithium battery. Through comparison of SOC-dQ/dV curves of the first cycle and the 300th cycle of the battery, it is found that the peak of the SOC-dQ/dV curve at 50% SOC decreases after the 300 cycles, and the peak of the SOC-dQ/dV curve at 80% SOC remains basically unchanged after the 300 cycles, which indicates that the battery lost lithium after the 300 cycles, and the peak of the SOC-dQ/dV curve at 50% SOC shifts slightly to the left, which indicates that a loss of a negative active material starts to appear. Although the peak of the SOC-dQ/dV curve at 80% SOC slightly shifts to the left, it can be seen from the figures that this is caused by the left shift of the peak of the SOC-dQ/dV curve at 50% SOC driving the whole curve to the left. However, the peaks of the SOC-dQ/dV curve as a whole shift to the direction of SOC decreasing, which indicates that the internal resistance of the battery increases with the charging and discharging cycles of the battery.

The execution orders of various steps enumerated in the present disclosure are only examples of the presently disclosed techniques, and are not intended to limit aspects of the method for analyzing battery life degradation presently disclosed. Any omission or replacement of the steps, and extra steps consistent with the principles of the present disclosure are within the scope of the present disclosure.

The present disclosure further provides a non-transitory computer-readable storage medium, storing a computer program. When the computer program is executed by a processor, the method for analyzing battery life degradation is implemented.

A person of ordinary skill in the art may understand that all or a part of the steps for implementing the above method embodiments may be completed by hardware related to the computer program. The foregoing computer program may be stored in a non-transitory computer-readable storage medium. When the program is executed, steps of the foregoing method embodiments are performed. The foregoing non-transitory computer-readable storage medium comprises various computer storage media such as a ROM, a RAM, a magnetic disk, an optical disk, or the like that can store program code.

Refer to FIG. 8, which is a block diagram of an electronic device according to an embodiment of present disclosure. As shown in FIG. 8, the electronic device 8 comprises a processor 81 and a memory 82. The memory 82 is configured to store a computer program, and the processor 81 is configured to execute the computer program stored in the memory, so that the electronic device 7 performs steps of the method for analyzing battery life degradation.

The above processor 81 may be a general-purpose processor, comprising a central processing unit (CPU), a network processor (NP), and the like. The processor may alternatively be a digital signal processor (DSP), an application specific integrated circuit (ASIC), a field programmable gate array (FPGA) or another programmable logic device, a discrete gate or a transistor logic device, or a discrete hardware assembly.

The memory 82 may comprise a random-access memory (RAM), or may comprise a non-volatile memory, for example, at least one magnetic disk memory.

In practical applications, the electronic device may be a computer comprising all or part of components such as a memory, a storage controller, one or more processing units (CPU), a peripheral interface, an RF circuit, an audio circuit, a speaker, a microphone, an input/output (I/O) subsystem, a display screen, another output or control device, and an external port. The computer comprises, but is not limited to, personal computers such as a desktop computer, a notebook computer, a tablet computer, a smart phone, and a personal digital assistant (PDA). In some other implementations, the electronic device may further be a server. The server may be arranged on one or more physical servers according to various factors such as functions and loads, or may be a cloud server composed of distributed or centralized server clusters, which is not limited in this embodiment.

In summary, the present disclosure provides a method for extracting a life degradation curve (that is, a dQ/dV curve of a lithium battery) under complex working conditions. The extraction method is simple and only requires obtaining a state of charge (SOC)-open circuit voltage (OCV) curve, thereby solving the problem in the prior that that it is difficult to accurately extract the dQ/dV curve of the battery under complex working conditions, and achieving desirable practical applicability under complex working conditions. The implementation of the method is efficient, as it occupies minimal memory space and does not interfere with other functions. Additionally, the speed of operation is impressive. For instance, when analyzing the life degradation of a certain battery or battery module using this method to extract the dQ/dV curve, it only takes about 1 second to process a whole day's worth of data. The present disclosure effectively overcomes various disadvantages in the prior art, and has high industrial utilization value.

The above embodiments describe the principle and efficacy of the present disclosure by using examples, and are not used to restrict the present disclosure. Any person familiar with this technology can modify or change the above embodiments without departing from the spirit and scope of the present disclosure. Therefore, all equivalent modifications or changes made by a person skilled in the art without departing from the spirit and technical ideas disclosed in the present disclosure shall still be covered by the claims of the present disclosure.

What is claimed is:

1. A method for analyzing battery life degradation, comprising:
obtaining battery data of a device, wherein the battery data comprises a voltage and a current of a battery of the device;
estimating an open circuit voltage of the battery based on the battery data;
establishing a function curve between a state of charge and the open circuit voltage of the battery;
extracting a life degradation curve based on the function curve; and
performing life degradation analysis on the battery based on the life degradation curve.

2. The method as in claim 1, wherein the step of establishing the function curve between the state of charge and the open circuit voltage of the battery comprises:
establishing an adaptive iterative calculation model, and estimating the open circuit voltage of the battery by using the adaptive iterative calculation model; and
obtaining the function curve between the state of charge and the open circuit voltage of the battery by polynomial fitting.

3. The method as in claim 2, wherein the step of establishing the adaptive iterative calculation model, and estimating the open circuit voltage of the battery by using the adaptive iterative calculation model comprises:
establishing the adaptive iterative calculation model based on a first-order RC equivalent circuit;
performing bilinear transformation on the adaptive iterative calculation model;
determining a to-be-estimated-parameter matrix and an input variable matrix; and
determining the open circuit voltage of the battery based on the to-be-estimated-parameter matrix and the input variable matrix.

4. The method as in claim 2, wherein the step of obtaining the function curve between the state of charge and the open circuit voltage of the battery by polynomial fitting comprises:
setting a forgetting factor, and setting an initial value of the forgetting factor, wherein the forgetting factor represents a degree to which an estimation result at a previous moment is forgotten;
adaptively adjusting the forgetting factor based on a preset condition during each iteration of the adaptive iterative calculation model;
inputting the voltage and the current of the battery and the state of charge of the battery into the adaptive iterative calculation model to obtain the open circuit voltage; and
obtaining the function curve between the state of charge and the open circuit voltage of the battery by polynomial fitting.

5. The method as in claim 1, wherein the step of extracting the life degradation curve based on the function curve comprises:
calculating capacity differentials based on the function curve,
which is performed every time the state of charge changes during a complete charging and discharging process; and
obtaining the life degradation curve based on the capacity differentials.

6. The method as in claim 1, wherein the step of obtaining the battery data of the device comprises:
continuously obtaining the battery data of the device at a preset data sampling interval.

7. The method as in claim 1, wherein before the step of obtaining the battery data of the device, the method further comprises:
obtaining a piece of battery data in advance, and analyzing an actual working condition of a power station based on the piece of battery data obtained in advance.

8. The method as in claim 1, wherein the step of performing life degradation analysis on the battery based on the life degradation curve comprises:
analyzing a life degradation mechanism of the battery based on variations of different peaks, position shifts of the peaks, and sharpness variations of the peaks of the life degradation curve, wherein analyzing the life degradation mechanism of the battery further comprises: analyzing a loss of circulating lithium and a loss of a negative active material through the variations of the peaks of the life degradation curve.

9. A non-transitory computer-readable storage medium, storing a computer program, wherein when the computer program is executed by a processor, the method for analyzing battery life degradation as in claim 1 is implemented.

10. An electronic device, comprising a processor and a memory, wherein
the memory is configured to store a computer program, and the processor is configured to execute the computer program stored in the memory, so that the electronic device performs the method for analyzing battery life degradation as in claim 1.
